(19) United States
(12) Patent Application Publication
(10) Pub. No.: US 2024/0147632 A1
(43) Pub. Date: May 2, 2024

(54) WIRING BOARD

(71) Applicant: YAZAKI CORPORATION, Tokyo (JP)

(72) Inventors: Mitsuaki Maeda, Makinohara-shi (JP); Yasutaka Hanaoka, Makinohara-shi (JP)

(21) Appl. No.: 18/476,308

(22) Filed: Sep. 28, 2023

(30) Foreign Application Priority Data
Oct. 31, 2022 (JP) 2022-174959

(51) Int. Cl. H05K 3/34; H05K 1/02; H05K 3/10

(52) U.S. Cl. CPC H05K 3/341; H05K 1/0296; H05K 3/103; H05K 2203/1194

(57) ABSTRACT

A wiring board includes a board including a board body and a plurality of electrodes, and an annealed copper wire connected between the electrode and the electrode. The plurality of electrodes are provided a front surface of the board body. Both ends of the annealed copper wire are soldered to the electrode. The annealed copper wire is mounted in contact with a front surface of the board from one end to the other end.

### CROSS-REFERENCE TO RELATED APPLICATIONS

This application is based on and claims priority under 35 USC 119 from Japanese Patent Application No. 2022-174959 filed on Oct. 31, 2022, the contents of which are incorporated herein by reference.

### TECHNICAL FIELD

The present invention relates to a wiring board.

### BACKGROUND ART

In the related art, accompanying automobile electrification, there is an increasing need to supply a large current to a wiring board mounted on a vehicle. Since a conductive pattern formed on the wiring board is very thin, it is necessary to increase a width of the conductive pattern in order to flow a large current. Alternatively, the conductive pattern needs to be formed in multilayers. When the width of the conductive pattern is increased as described above, a mounting space for an electronic component is reduced. When the conductive pattern is formed in multilayers, the cost increases. Therefore, there is a problem that a large current cannot be flowed at low cost while securing a mounting space for the electronic component.

Therefore, a wiring board has also been proposed in which bonding wires are ultrasonically connected between conductive lands constituting a large current circuit (Patent Literatures 1 and 2). However, in the bonding wire, since a wire diameter thereof is small and heat generation suppression is not sufficient, a large current cannot be flowed.

It is also conceivable to use a bus bar or a copper rod instead of the conductive pattern. However, there are problems that the bus bar is costly in machining, and that only a linear pattern can be formed with a copper rod and thus the design is limited.

### CITATION LIST

### Patent Literature

Patent Literature 1: JPH10-303520A
Patent Literature 2: Japanese Patent No. 2953893B

### SUMMARY OF INVENTION

The present invention has been made in view of the above circumstances, and an object of the present invention is to provide a wiring board capable of allowing a large current to flow at low cost while securing a mounting space for an electronic component, and suppressing limitation on design.

In order to achieve the above object, a wiring board according to the present invention is characterized by the following.

According to the present invention, it is possible to provide a wiring board capable of allowing a large current to flow at low cost while securing a mounting space for an electronic component, and suppressing limitation on design.

The present invention has been briefly described above. Further, details of the present invention can be clarified by reading modes for carrying out the invention (hereinafter, referred to as “embodiments”) described below with reference to the accompanying drawings.

### BRIEF DESCRIPTION OF DRAWINGS

FIG. 1 is a top view of a wiring board according to a first embodiment of the present invention;

FIG. 2 is a cross-sectional view taken along a line A-A in FIG. 1;

FIG. 3 is a cross-sectional view taken along a line B-B in FIG. 1;

FIG. 4 is a top view of a wiring board according to a second embodiment of the present invention; and

FIG. 5 is a cross-sectional view taken along a line C-C in FIG. 4.

### DESCRIPTION OF EMBODIMENTS

### First Embodiment

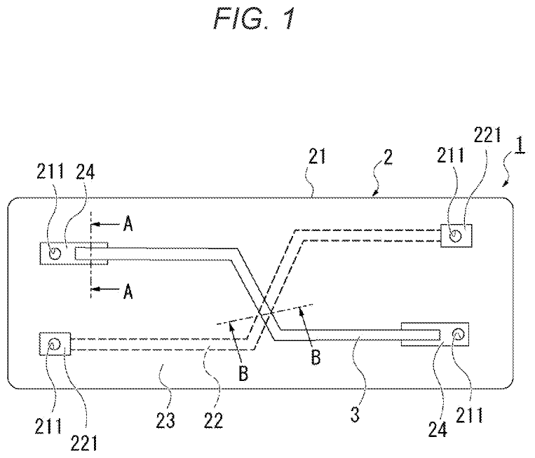

A first embodiment of the present invention will be described below with reference to FIGS. 1 to 3.

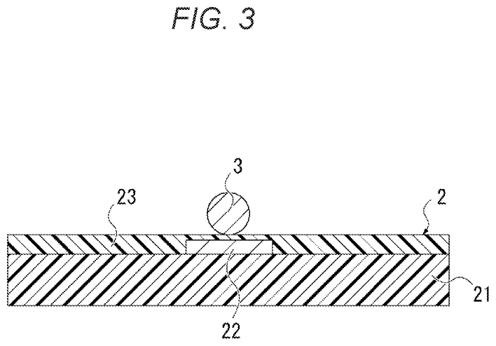

As illustrated in FIGS. 1 to 3, a wiring board 1 includes a board 2 and an annealed copper wire 3 mounted on the board 2. First, a configuration of a general board 2 will be described. As illustrated in FIGS. 1 and 3, the board 2 includes a board body 21, a conductive pattern 22 provided on a front surface of the board body 21, and a resist layer 23 covering the conductive pattern 22.

As illustrated in FIG. 1, the board body 21 is provided with through holes 211 into which leads of electronic components such as fuses and relays are inserted. Electrodes 221 to which electronic components such as fuses and relays are connected are provided at both ends of the conductive pattern 22. The electrode 221 is provided in a manner of surrounding the through hole 211. The electrode 221 is connected, by soldering, to a lead of an electronic component inserted into the through hole 211.

As illustrated in FIG. 3, the resist layer 23 is provided in a manner of covering the conductive pattern 22, and insulates the conductive pattern 22. As illustrated in FIG. 1, the resist layer 23 on the electrode 221 is removed, and the electrode 221 is exposed from the resist layer 23 and can be connected to an electronic component.

The board 2 of the present embodiment further includes a plurality of electrodes 24. The electrode 24 is provided on an upper surface of the board body 21 so as to surround the through hole 211. The resist layer 23 on the electrode 24 is also removed, and the electrode 24 is also exposed from the resist layer 23. The electrode 24 is connected, by soldering, to a lead of an electronic component inserted into the through hole 211.

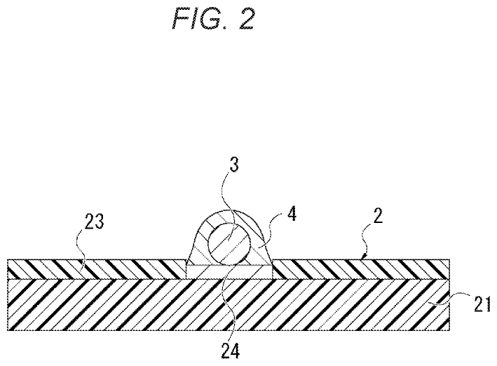

The annealed copper wire 3 is a flexible and deformable conductive wire. The annealed copper wire 3 have a circular cross section with a diameter of 1 mm to 3 mm, and can flow a current of 10 A or more. Both ends of the annealed copper wire 3 are soldered to the electrodes 24, respectively. As illustrated in FIG. 2, both ends of the annealed copper wire 3 are stacked on the electrodes 24, respectively, and a solder 4 is provided thereon. The electrode 24 and the electrode 24, which are connected to both ends of the annealed copper wire 3 respectively, are independently provided on the board body 21 without being electrically connected. That is, the conductive pattern connecting the electrode 24 and the electrode 24 is not provided on the board body 21. Therefore, when the annealed copper wire 3 is not connected, the electrode 24 and the electrode 24 are not electrically connected. The annealed copper wire 3 is mounted in a manner of being in contact with a front surface of the board 2 from one end to the other end thereof. In the present embodiment, the annealed copper wire 3 are mounted on the front surface of the board 2 in a bent manner.

The annealed copper wire 3 is drawn out from annealed copper wires wound in a reel shape, shaped into a shape like a conductive pattern, cut, and then mounted on the board 2. Accordingly, any shape can be formed from one annealed copper wire 3, and versatility thereof is excellent.

According to the above-described embodiment, the annealed copper wire 3 is connected between the electrode 24 and the electrode 24, and both ends thereof are soldered to the electrodes 24, respectively. The annealed copper wire 3 is routed in contact with the front surface of the board 2 from one end to the other end thereof. The annealed copper wire 3 has a larger cross-sectional area than the conductive pattern and has reduced wiring resistance, and thus heat generation thereof can be reduced. Accordingly, heat generation can be suppressed by using the annealed copper wire 3 having a larger cross-sectional area than the conductive pattern, and thus a large current can be allowed to flow between the electrode 24 and the electrode 24. That is, there is no need to provide a wide conductive pattern that allows a large current to flow, and there is no need to form the conductive pattern in multilayers in order to flow a large current. Accordingly, a large current can be flowed at low cost while securing a mounting space for an electronic component. Since the flexible and deformable annealed copper wire 3 is used, the annealed copper wire 3 can be mounted on the board 2 in a bent manner as illustrated in FIG. 1. Therefore, it is possible to suppress limitation on the design such as arrangement of the electrode 24.

In addition, since the annealed copper wire 3 has a significantly larger cross-sectional area than the conductive pattern having a very small thickness, the heat generation of the wiring board 1 can be significantly reduced.

According to the above-described embodiment, the electrode 24 and the electrode 24 are independently provided on the board body 21 without being electrically connected. Accordingly, as illustrated in FIG. 3, another conductive pattern 22 insulated from the annealed copper wire 3 can be disposed under the annealed copper wire 3, and thus the limitation on design can be further suppressed.

### Second Embodiment

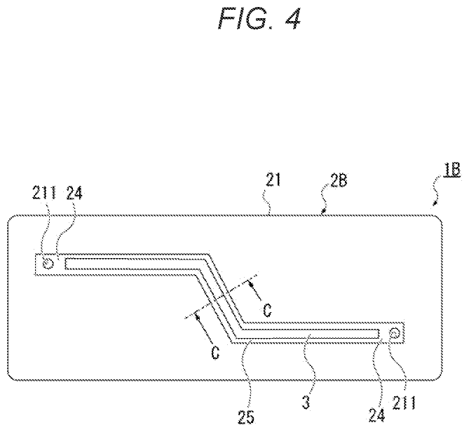

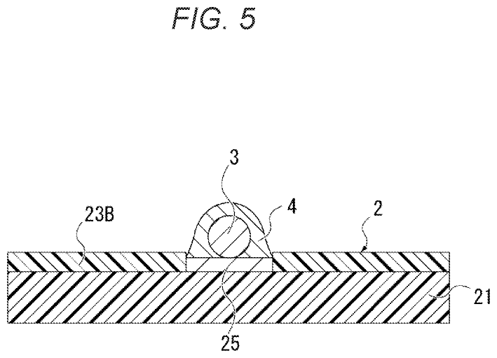

Next, a second embodiment will be described below with reference to FIGS. 4 and 5. In FIGS. 4 and 5, the same reference signs are given to the same parts as those of the wiring board 1 illustrated in FIGS. 1 to 3 already described in the first embodiment, and a detailed description thereof will be omitted.

As illustrated in FIGS. 4 and 5, a wiring board 1B includes a board 2B and the annealed copper wire 3 disposed on the board 2B. The board 2B includes the board body 21, a plurality of electrodes 24 provided on a front surface of the board body 21, a conductive pattern 25, and a resist layer 23B. Since the board body 21 and the electrodes 24 are similar to those in the first embodiment, a detailed description thereof is omitted here.

The conductive pattern 25 connects the electrode 24 and the electrode 24, and is bent in the present embodiment. The resist layer 23B is provided in a manner of covering the front surface of the board body 21. In the present embodiment, the resist layer 23B on the electrode 24 and the conductive pattern 25 is removed, and the electrode 24 and the entire conductive pattern 25 from one end to the other end are exposed.

Similarly to the first embodiment, the annealed copper wire 3 is a flexible and deformable conductive wire. The annealed copper wire 3 have a circular cross section with a diameter of 1 mm to 3 mm, and can flow a current of 10 A or more. In the second embodiment, similarly to the first embodiment, both ends of the annealed copper wire 3 are soldered to the electrodes 24, respectively, and a center of the annealed copper wire 3 is soldered to the conductive pattern 25. That is, as illustrated in FIG. 5, the center of the annealed copper wire 3 is stacked on the conductive pattern 25, and the solder 4 is provided thereon. In the present embodiment, the entire annealed copper wire 3 from one end to the other end is soldered to the conductive pattern 25 and the electrodes 24.

According to the above-described embodiment, the center of the annealed copper wire 3 is soldered to the conductive pattern 25. Accordingly, an area of a current path between the electrode 24 and the electrode 24 is increased by the amount corresponding to the conductive pattern 25, and heat generation can be reduced. Further, when a large current of, for example, about 60 A to 70 A is required to flow after the design of the wiring board 1 is completed, the annealed copper wire 3 can be mounted by changing a width of the resist layer 23B to expose the conductive pattern 25. Therefore, it is possible to minimize a design change for a post-installed heat countermeasure component. When it is not necessary to flow a large current, the resist layer 23B covers the conductive pattern 25.

The present invention is not limited to the embodiments described above, and modifications, improvements, and the like can be made as appropriate. In addition, materials, shapes, sizes, numbers, arrangement positions, and the like of components in the above-described embodiments are freely selected and are not limited as long as the present invention can be implemented.

Although a wire of which a conductive core wire is exposed is used as the annealed copper wire 3 in the first embodiment described above, the present invention is not limited thereto. A coated electric wire may be used as the annealed copper wire 3, and a core wire exposed by peeling a coating at both ends may be connected to the electrode 24. By using the coated electric wire, a central portion of the annealed copper wire 3 can be insulated.

Although in the first embodiment described above, as illustrated in FIG. 3, the conductive pattern 22 insulated from the annealed copper wire 3 is routed under the annealed copper wire 3, the present invention is not limited thereto. It is not essential to provide the conductive pattern 22 insulated from the annealed copper wire 3 under the annealed copper wire 3, and the conductive pattern 22 may not be provided depending on the design.

Although an electrode for insertion mounting provided around the through hole 211 is used as the electrode 24 in the embodiments described above, the present invention is not limited thereto. As the electrode 24, an electrode for surface mounting may be used.

The annealed copper wire 3 used in the above-described embodiments may be plated with nickel (Ni) or tin (Sn) to improve solderability.

Although a single annealed copper wire 3 is connected between the electrode 24 and the electrode 24 in the above-described embodiments, the present invention is not limited thereto. A plurality of annealed copper wires 3 connected in parallel may be connected between the electrode 24 and the electrode 24. Accordingly, a cross-sectional area of a current path between the electrode 24 and the electrode 24 is further increased, and heat generation can be further reduced.

Although the annealed copper wire is mounted on the board in a bent manner in the above-described embodiments, the present invention is not limited thereto. Depending on the design of the wiring board, the annealed copper wire may be mounted linearly.

Here, features of the embodiment of the wiring board according to the present invention described above are briefly summarized and listed in the following [1] to [5]. [1] A wiring board (1, 1B) including:
a board (2, 2B) including a board body (21) and a plurality of electrodes (24), the plurality of electrodes (24) being provided on a front surface of the board body (21) and to be connected to an electronic component; and
an annealed copper wire (3) connected between the electrode (24) and the electrode (24) and having both ends soldered to the electrode (24), in which
the annealed copper wire (3) is mounted in contact with a front surface of the board (2, 2B) from one end to the other end.

According to the configuration of the above [1], by using the annealed copper wire (3), it is not necessary to provide a wide conductive pattern that allows a large current to flow, and it is not necessary to form a conductive pattern in multilayers in order to flow a large current. Accordingly, a large current can be flowed at low cost while securing a mounting space for an electronic component. Further, since the annealed copper wire (3) that is flexible and deformable is used, the annealed copper wire (3) can be mounted on the board (2) while being bent like a conductive pattern. Therefore, it is possible to suppress limitation on the design.

[2] In the wiring board (1) according to [1],

the electrode (24) and the electrode (24), to which both ends of the annealed copper wire (3) are connected respectively, are independently provided on the board body (21) without being electrically connected.

According to the configuration of [2], since another conductive pattern (22) insulated from the annealed copper wire (3) can be disposed under the annealed copper wire (3), it is possible to further suppress the limitation on design.

[3] In the wiring board (1B) according to [1],
a conductive pattern (25) is provided on the front surface of the board body (21) and connects the electrode (24) and the electrode (24), and
a center of the annealed copper wire (3) is soldered to the conductive pattern (25).

According to the configuration of [3], an area of a current path between the electrode (24) and the electrode (24) can be increased by the amount corresponding to the conductive pattern (25), and heat generation can be reduced. Further, when a large current needs to flow after the design of the wiring board (1B) is completed, the annealed copper wire (3) can be mounted by changing a width of a resist layer to expose the conductive pattern (25). Therefore, it is possible to minimize a design change for a post-installed heat countermeasure component.

[4] In the wiring board (1, 1B) according to [1],

the annealed copper wire (3) is implemented by a coated electric wire.

According to the configuration of [4], a central portion of the annealed copper wire (3) can be insulated.

[5] In the wiring board (1, 1B) according to [1],

a plurality of the annealed copper wires (3) connected in parallel are connected between the electrode (24) and the electrode (24).

According to the configuration of [5], a cross-sectional area of the current path between the electrode (24) and the electrode (24) is increased, and the heat generation can be further reduced.

What is claimed is:

1. A wiring board comprising:
a board including a board body and a plurality of electrodes, the plurality of electrodes being provided on a front surface of the board body and to be connected to an electronic component; and
an annealed copper wire connected between the electrode and the electrode and having both ends soldered to the electrode, wherein
the annealed copper wire is mounted in contact with a front surface of the board from one end to another end.

2. The wiring board according to claim 1, wherein
the electrode and the electrode, to which both ends of the annealed copper wire are connected respectively, are independently provided on the board body without being electrically connected.

3. The wiring board according to claim 1, further comprising:
a conductive pattern provided on the front surface of the board body and connecting the electrode and the electrode, wherein
a center of the annealed copper wire is soldered to the conductive pattern.

4. The wiring board according to claim 1, wherein
the annealed copper wire is constructed by a coated electric wire.

5. The wiring board according to 1, wherein
a plurality of the annealed copper wires connected in parallel are connected between the electrode and the electrode.
